(19) United States
(12) Patent Application Publication
(10) Pub. No.: US 2026/0247491 A1
(43) Pub. Date: Aug. 20, 2026

(54) SYSTEMS FOR EMITTING UNCOOLED LIGHT

(71) Applicant: ALMAE TECHNOLOGIES, Marcoussis (FR)

(72) Inventor: Hélène Debregeas, Boullay Les Troux (FR)

(73) Assignee: ALMAE TECHNOLOGIES, Marcoussis (FR)

(21) Appl. No.: 18/035,034

(22) PCT Filed: Nov. 2, 2021
(86) PCT No.: PCT/EP2021/080379

§ 371 Date: Apr. 21, 2025

(30) Foreign Application Priority Data
Nov. 2, 2020 (FR) 2011235

(51) Int. Cl. H05B 1/02; H05B 3/00

(52) U.S. Cl. CPC H05B 1/02; H05B 3/0033; H05B 2203/032; H05B 2203/037

(57) ABSTRACT

An uncooled light-emitting system includes a light-emitting device. The light-emitting device includes at least one first set of layers of semiconductor materials configured to form at least one first active zone able to emit light and a heater. The first active zone is optimized to function at a nominal temperature. The heater extends at least along the first active zone and is situated at a predetermined maximum distance from the first active zone less than or equal to 100 micrometers. The heater is configured, in operation, to produce a heating of the first active zone. A control unit is configured to start up the heater only if the temperature of the device is determined to be strictly lower than a predetermined set point temperature less than or equal to the nominal temperature.

### TECHNICAL FIELD OF THE INVENTION

The invention concerns uncooled light-emitting systems and in particular uncooled light-emitting systems for telecommunication systems.

### PRIOR ART

Telecommunication systems generally comprise Semiconductor optical devices enabling emission of an optical signal that can be modulated. Depending on the distance over which the optical signal must be transported, these devices may comprise: continuous lasers (hereinafter LC), directly modulation lasers (hereinafter DML), which have an active zone enabling the emission of a directly modulated optical signal, and externally modulated lasers (hereinafter EML) comprising an active zone enabling the emission of an optical signal (hereinafter referred to as the “laser part” or simply the “laser”) and an active zone enabling modulation of that optical signal (hereinafter referred to as the “modulator part” or simply the “modulator”). The modulator of an EML is for example an electro-absorption modulator (hereinafter EAM).

Generally speaking, a zone in a semiconductor optical device is “active” when it is: able to generate a modification of an optical property of a light beam when it is subjected to a source of current or of voltage. For example an active zone is therefore configured for the emission of light or the modulation of light. The laser of a DML or of an EML is in particular characterized by two parameters, the gain curve g(λ) of the laser, which represents the gain of the laser as a function of the wavelength, and the emission wavelength of the laser. For an optimum laser output power the laser is optimized to function at a nominal temperature at which the maximum of the gain curve is close to the emission wavelength of the laser and is at a sufficient level to enable an output power matching the application.

When the laser is placed in an environment subject to temperature variations the wavelength corresponding to the maximum gain of the laser and the emission wavelength of the laser vary differently with the temperature of the device. Thus, as shown in FIG. 1, if the temperature of the device departs from the nominal temperature the emission wavelength of the laser is offset relative to the maximum gain of the laser. This implies an increase in the threshold current of the laser and a decrease of the optical power emitted by the laser, which is prejudicial for the application.

Also the gain tends to decrease if the temperature of the device departs from the nominal operating temperature, which also degrades the optical power.

In the case of an EML the performance of the modulator is characterized in particular by a curve of the evolution of the optical power transmitted by the modulator (its extinction curve) at an operating wavelength (for example the emission wavelength of the laser) as a function of a supply voltage of the modulator. The extinction curve also varies with temperature.

In particular, as depicted in FIG. 2, for use at a nominal temperature the extinction curve 202 is steep and configured so that two supply voltages of the modulator, for example 0 V and −1 V, enable switching between two states of the modulator corresponding to two different levels of absorption: a state allowing passage of light at the operating wavelength (a passing state, low absorption by the modulator) and a state allowing passage of little of the light at the operating wavelength (a blocking state, high absorption by the modulator). On the other hand, for a temperature departing from the nominal temperature the modulator may absorb too great a portion of the light that it receives from the laser in the passing state, which reduces the output power of the EML (as shown by the curve 204), or may not absorb enough light in the blocking state (as shown by the curve 206), which implies using a higher supply voltage (for example −2 V instead of −1 V) and therefore a greater consumption of energy.

The aforementioned optical devices are therefore generally integrated into a cooled light-emitting system in which they are accompanied by a temperature regulating system (for example a Peltier effect thermoelectric system) able to heat and to cool the laser and/or modulator parts of the devices and ensuring that they are maintained at the nominal temperature. In practice a nominal temperature around 45° C. is often chosen because such a temperature is found in the middle of a usual range of temperature variations to which the environment of the device is subjected.

However, in these systems temperature regulation contributes strongly to the overall consumption of electrical energy. In particular the cooling function causes highly energy consumtion when the required temperature difference is high, which is often the case in installations containing a large number of devices powered electrically.

Because H this, systems with no temperature cooling function, termed uncooled systems in the present description, are preferred for applications such as access networks, which must be low cost, or data centers, which consume large amounts of energy.

In these systems the aim is therefore to limit the variations in the performance of the light-emitting device if the system is placed in an environment subject to typical temperature variations, for example a temperature range extending between about 0° C. and about 85° C. for DMLs and between 20° C. and 70° C. for EMLS.

In the prior art a number of solutions have been proposed to reduce the technical problems referred to hereinabove and to obtain a device emitting an optical signal the characteristics of which are not excessively degraded in the event of temperature variations without requiring cooling of the device.

The document N. Sasada et al. [Ref. 1] discloses a technique for maintaining a high gain of a laser at high temperatures that consists in optimizing an active zone of a light-emitting device. This solution makes it possible for example to achieve functioning of the laser part of an optical device up to 80° C. with sufficient gain. However, the technique does not solve the problem of variation of the emission wavelength of the laser part relative to the gain curve, which degrades the emission power of the laser in the event of a temperature variation.

The document Y. Nakai et al. [Ref. 2] discloses a solution for minimizing the variations of the extinction curve of the EAM of an EML. In this solution the active zone that constitutes the EAM is optimized to form a multiple quantum well vertical structure making it possible to obtain a very steep extinction curve of the EAM such that modulation performance remains correct despite temperature variations. This solution enables good performance to be achieved in the temperature range 20-70° C.; nevertheless, at high temperatures the absorption by the modulator becomes too great and at low temperatures the modulation voltage of the EAM must be increased to obtain satisfactory switching.

Further, in order to reduce the extinction curve variations of the EAM with temperature it has been proposed to implement a heater along an EAM optimized at high temperature, as disclosed in the patent document EP 1 281 998. However, this latter document does not address maintaining the performance of a laser in the event of a temperature variation.

An objective of the present descryption is to propose a new uncooled light-emitting system enabling the problems of the prior art to be solved.

### SUMMARY OF THE INVENTION

In the present description the term “comprise” means the same thing as “include” or “contain” and is inclusive or open and does not exclude other elements not described or represented.

Further, in the present description the term “about” or “substantially” is synonymous with (means the same thing as) an upper and/or lower margin of 10%, for example 5%, of the respective value.

In a first aspect, the present description concerns an uncooled light-emitting system comprising:
a light-emitting device comprising:
at least one first set of layers of semiconductor materials configured to form at least one first active zone able to emit light, said first active zone being optimized to function at a nominal temperature; and
a heater extending at least along said first active zone and situated at a predetermined maximum distance from said first active zone, said heater being configured, in operation, to produce a heating of said first active zone;
means for determining the temperature of the device; and
a control unit configured to start up said heater only if said temperature of the device is strictly lower than a predetermined set point temperature less than or equal to said nominal temperature, the heating produced by the heater enabling a rise in the temperature of the device to about the value of the set point temperature. In accordance with one or more embodiments the maximum distance between the active zone and the heater is a distance less than or equal to 100 micrometers, for example a distance less than or equal to 100 micrometers over at least 70% of the length of the first active zone. In accordance with one or more examples, the maximum distance between the active zone and the heater is a distance between about 5 micrometers and about 100 micrometers, preferably between about 5 micrometers and about 20 micrometers, for example over at least 70% of the length of the first active zone.

Such a distance enables the heater to effectively heat the first active zone while leaving a sufficient space between a contact electrode of the laser and the heater to prevent electrical conduction between these two components.

In the present description the temperature of the device is to be understood as being the mean temperature of the device; this temperature may be considered as substantially equal to the temperature of the active zone or zones of the device, also termed the junction temperature of the device by the person skilled in the art.

In the present description the nominal temperature of the device is the temperature of the device for which the device has been optimized during manufacture in order to function optimally, that is to say the temperature of the device for which the device emits the highest optical power. This temperature is generally indicated by the manufacturer.

In the absence of heating of the active zone or zones by the heater the temperature of the device is near an exterior temperature of the device, that is to say a temperature of an environment in which the device is placed, or significantly higher because of heating of the device linked to its operation. The temperature of the device is therefore subject to variations in the exterior temperature and may depart from the nominal operating temperature, which degrades the performance of the device.

Operating the heater only when the temperature of the device is strictly lower than a predetermined set point temperature lower than or equal to the nominal temperature enables improvement of the performance of the system compared to a prior art system whilst maintaining a low consumption of electrical energy.

The set point temperature is a temperature selected so that the operation of the device approaches the optimum operation when the heater is operating, that is to say the temperature of the device is closer to the nominal temperature than the temperature of the device that would be obtained if the device had no heater or the heater were not operating.

In accordance with one or more embodiments said set point temperature is about equal to the nominal operating temperature of the device.

This is particularly advantageous in the situation where the nominal operating temperature is approximately equal to an estimated maximum value of the temperature of the environment. In fact, heating the active zone or zones maintains the device at the nominal operating temperature and the variations in the performance of the device in the event of variations of the exterior temperature are cancelled out.

In particular, the emission wavelength of the device in the event of variations of the exterior temperature remains stable, which renders possible the use of telecommunication channels at closer together wavelengths in order to increase the overall bit rate of an optical telecommunication network.

In accordance with one or more embodiments said set point temperature is strictly lower than said nominal temperature of operation of the device.

This makes it possible to limit the range of variation of the temperature of the device relative to the range of variation of the exterior temperature and to reduce the excess electrical energy consumption of the heater because the range of exterior temperature for which the heater operates is restricted. This improves the performance of the device compared to a prior art device while reducing the excess consumption of electrical energy by the heater.

In accordance with one or more embodiments the means for determining the temperature of the device comprise a temperature sensor.

In accordance with one or more embodiments the temperature sensor is in thermal contact with said at least one first active zone of the device.

By virtue of this thermal contact the sensor enables precise measurement of the temperature of the device. To this end the sensor may for example be disposed on the same base as the light-emitting device.

In accordance with one or more embodiments the temperature sensor is thermally insulated from said at least one first active zone of the device. The sensor then enables measurement of the exterior temperature.

As the temperature of the device is substantially equal to the exterior temperature when the heater is not operating, measuring the exterior temperature therefore enables estimation of the temperature of the device and determination of whether it is useful to start up the heater.

The temperature sensor may for example be placed in the same package as the device but at a sufficiently great distance from the device for the heating produced by the heater not to influence the measurement of temperature by the temperature sensor.

In other embodiments the sensor may be physically separated from the device by a thermal insulation material so that the heating produced by the heater does not influence the measurement of temperature by the temperature sensor. Thermal insulation is typically sufficient if the sensor is not heated by more than 5° C. because of the heating by the heater.

In accordance with one or more embodiments, and in particular in embodiments in which the temperature sensor measures the exterior temperature, it is useful beforehand to effect a calibration of the control unit to determine an electrical power to be supplied to the heater for the heating produced by the heater to raise the temperature of the device to the set point temperature.

In accordance with one or more embodiments the means for determining the temperature of the device comprise a device for measuring the wavelength (or the frequency) of the light emitted by the light-emitting device.

As the wavelength emitted by the light-emitting device depends on the temperature of the device, measuring said wavelength enables determination of the temperature of the device and deduction therefrom whether it is useful to start up the heater. To this end the temperature of the device deduced from the measured wavelength is compared to the set point temperature value and if the temperature of the device is strictly lower than the set point temperature the heater is started up.

In accordance with one or more embodiments said first set of layers of semiconductor materials is further configured to form a second active zone able to receive and to modulate light emitted by said first active zone, said second active zone being optimized to function at said nominal temperature, and said heater further extends along said second active zone and is disposed at said maximum distance from said second active zone, said heater being further configured to produce a heating of said second active zone.

This enables heating of the first active zone and the second active zone of the device so that the temperature of the device approximates the nominal operating temperature. In particular this enables improvement of the performance of a light-emitting device comprising both a laser and a modulator in the event of a variation of the exterior temperature.

In accordance with other embodiments the device may comprise a second set of layers of semiconductor materials configured to form a second active zone able to receive and to modulate light emitted by said first active zone, said second active zone being optimized to function at said nominal temperature, and said heater further extends along said second active zone and is disposed at said maximum distance from said second active zone, said heater being further configured to produce a heating of said second active zone.

Said second set of layers of semiconductor materials is disposed so as to be able to receive light emitted by the first set of layers of semiconductor materials. The arrangement of the first and second sets of layers of semiconductor materials may for example be produced using the butt-joint technique, that is to say arranging the first and second sets of layers of semiconductor materials end-to-end with their active zones aligned the one relative to the other and in contact, using a technique known to the person skilled in the art.

In accordance with one or more embodiments said second active zone forms an electro-absorption modulator.

In accordance with one or more embodiments said first active zone constitutes a distributed Bragg grating laser.

In accordance with one or more embodiments the heater comprises a metal strip disposed on an external layer of said set of layers of semiconductor materials.

The applicants have shown that the metal strip enables heating of the active zone or zones of the device, for example by the Joule effect.

In accordance with one or more embodiments the heater is produced in layers of the set of layers of semiconductor materials in the form of PN or PIN diode.

The applicants have shown that this PN or PIN diode produces heating in the set of layers of semiconductor materials facilitating heating of the active zone or zones of the device.

In accordance with one or more embodiments said heater comprises at least one ground electrically connected to a ground of said set of layers of semiconductor materials and at least one electrical contact electrically insulated from said ground.

This enables a common ground to be used for the device, which simplifies the electrical connection and the control of the device.

In accordance with one or more embodiments said heater is controlled by a current control set point.

In accordance with one or more embodiments said heater is controlled by a voltage control set point.

In a second aspect the present invention concerns a method of controlling the temperature in an uncooled light-emitting system in accordance with the first aspect, said method comprising:
choosing a set point temperature lower than or equal to said nominal temperature of the device,
determining the temperature of the device, and
the control unit starting up the heater only if said temperature of the device is strictly lower than said set point temperature, the heating produced by the heater enabling a rise in the temperature of the device to about the value of set point temperature.

In accordance with one or more embodiments the method further comprises prior calibration of the control unit, said calibration comprising establishing a power-heating characteristic that characterizes the rise in temperature the device as a function of an electrical power supplied to the heater by the control unit to produce heat.

### BRIEF DESCRIPTION OF THE FIGURES

Other advantages and features of the invention will become apparent on reading the description illustrated by the following figures:

FIG. 1, already described, represents the spectral power of the “laser” part of an example of a prior art light-emitting device for a temperature varying from 20° C. to 80° C.;

FIG. 2, already described, represents schematically a curve (an extinction curve) of the power transmitted by the “modulator” part of one example of a prior art light-emitting device in the case of use at a nominal temperature, for example 45° C., in the case of a temperature much higher than the nominal temperature, for example 80° C., and in the case of a temperature much lower than the nominal temperature, for example 20° C.;

FIG. 3A represents a schematic of one example of a light-emitting system according to the present invention in which the means for determining the temperature of the device comprise a temperature sensor thermally insulated from the active zone of the light-emitting device;

FIG. 3B represents a schematic of one example of a light-emitting system in accordance with the present description in which the means for determining the temperature of the device comprise a temperature sensor in thermal contact with the active zone of the light-emitting device;

FIG. 4A represents schematically a view from above of one example of a light-emitting device in accordance with the present description in which the heater comprises a metal strip;

FIG. 4B represents schematically a view in section of the light-emitting device depicted in FIG. 4A;

FIG. 5 represents schematically a view in section of one example of a light-emitting device in accordance with the present description in which the heater comprises a PN diode;

FIG. 6 represents schematically a view from above of one example of a light-emitting device in accordance with the present description comprising two active zones.

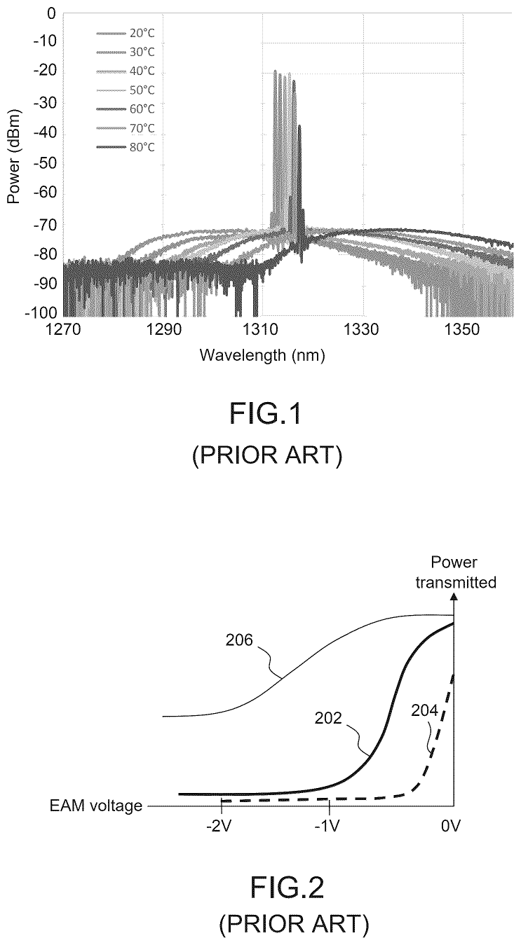

### DETAILED DESCRIPTION OF THE INVENTION

For clarity some elements are not represented to scale in the figures.

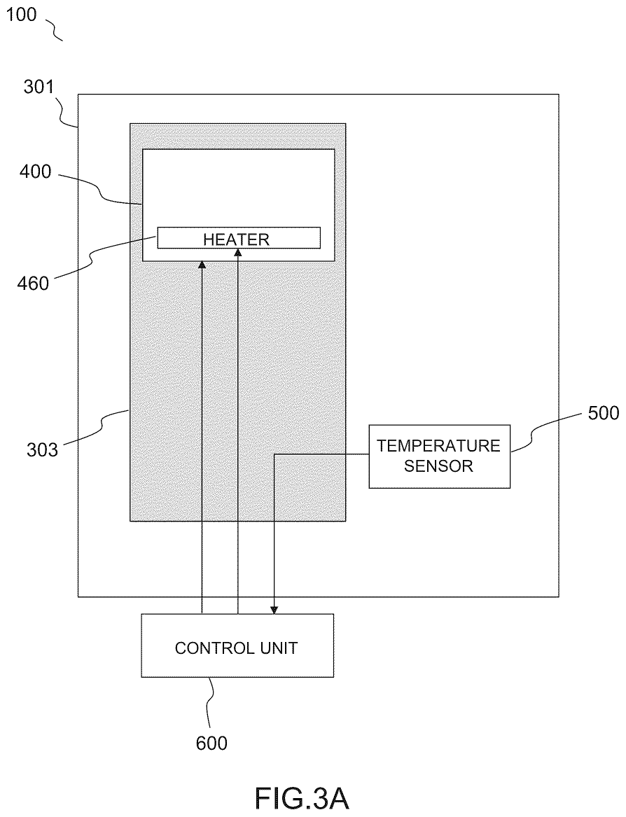

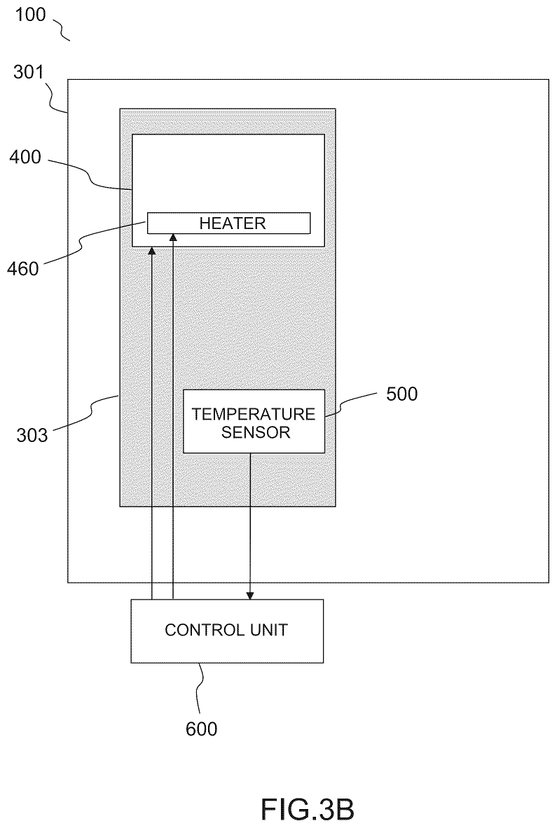

FIGS. 3A-3B represent schematically uncooled light emitting systems 100 in accordance with the present description comprising a light-emitting device 400 with a heater 460, a control unit 600 and means for determining the temperature of the device, comprising for example a temperature sensor 500.

The light-emitting device 400 is a device based on semiconductor materials and configured to emit light. In accordance with one or more embodiments the device 400 may have one or more optical functions, for example emission of continuous light or emission of modulated light.

Light-emitting devices in accordance with the present description are devices comprising semiconductor materials forming one or more active zones enabling the emission of light.

In accordance with the present description the operation of one or more active zones of the device is optimized at a given nominal temperature and the device is provided with a heater so that, if the temperature of the device is below a set point temperature, the active zone or zones of the device is or are heated to raise the temperature of the device to said set point temperature, which in general is close to the nominal temperature.

In practise, in a light-emitting device in accordance with the present description a “higher” nominal temperature could be used, that is to say a nominal temperature above the nominal temperatures mostly used in prior art devices, for example a temperature higher than about 45° C., preferably higher than or equal to about 70° C.

The control unit 600 comprises for example an electronic circuit configured to send electrical signals to the light-emitting device 400 in order to control optical functions of the device 400. In particular, the control unit 600 can activate or deactivate emission of light or modulation of the emitted light.

The control unit 600 is moreover configured to supply electrical power enabling activation or non-activation of the heater and heating by the heater producing the rise in temperature of the device to the set point temperature.

The device 400 may be fixed to a base 303 configured to enable coupling between electrodes of the device 400 and the electrical signals emitted by the control unit 600. The device 400 may be fixed to the base 303 by means of a layer of solder that for example comprises a gold-tin alloy.

The base 303 may comprise silicon nitride or aluminum nitride (AlN) and has dimensions of a few mm² (for example between about 4 mm² and about 2mm² ).

The uncooled light-emitting system 100 may include an optical package 301 (for example of transmit optical sub-assembly (TOSA) type) comprising for example the base 303 on which the device 400 is arranged and optionally comprising the temperature sensor 500, the package being configured to enable optical coupling of the optical signal (the light) emitted by the device 400 with optical components that are not represented, for example optical fibers.

The control unit 600 is outside the package.

Generally speaking the heater 460 is configured to be started up if the temperature of the device is strictly below a set point temperature, for example between about 40° C. and about 85° C. for a nominal temperature between about 60° C. and about 85° C., and to produce heat enabling the temperature of the device to be raised to the set point temperature.

The means for determining the temperature of the device are configured to estimate or to measure the temperature of the device and to activate or not heating by the heater.

The means for determining the temperature of the device may comprise a sensor 500 enabling measurement of temperature, for example a thermistor.

In some embodiments, one example of which is depicted in FIG. 3A, these means comprise a temperature sensor 500 arranged in the optical package 301 but thermally insulated from the device 400 and to be more precise from the active one of the device. In particular, the temperature sensor is not fixed to the base 303 to avoid thermal contact with the device 400. The sensor therefore measures the temperature of the environment in which the package 301 is placed, that is to say the exterior temperature. In the absence of heating by the heater the temperature of the device is substantially equal to the exterior temperature and the temperature sensor 500 enables the temperature of the device to be estimated. When the heater is operating and heating the device the temperature of the device may be evaluated from the previous calibration of determination of the power injected into the heater-heating of the device characteristic.

In some embodiments, one example of which is depicted in FIG. 3B, these means may comprise a temperature sensor placed directly on the base 303 and in thermal contact with the active zone or zones of the device to enable precise measurement of the temperature of the device.

In other embodiments the means 500 for determining the temperature of the device may comprise a device (not represented in the figures) that measures the wavelength emitted by the device and supplies at its output an estimate of the temperature of the device based on said measured wavelength.

In embodiments of the device in which the determination means comprise a temperature sensor thermally insulated from the active zones or zones of the device the prior calibration of the device may be effected to establish the electrical power that the control unit will supply to the heater so that heating by the heater can raise the temperature of the device to the set point temperature value.

Calibration may be effected by determining a power-heating characteristic that characterizes the rise in the temperature of the device as a function of the electrical power supplied to the heater by the control unit.

This characteristic may for example be obtained by measuring the temperature variations of the device as a function of the electrical power supplied to the heater by the control unit. To this end it is possible to proceed by the control unit injecting a plurality of current values I into the heater and, for each of these, measuring the voltage U at the terminals of the heater and the wavelength emitted by the device, in order to deduce therefrom a coefficient a characterizing the variation of the wavelength A with the electrical power UI supplied by the control unit (the coefficient a may be expressed in nm/W). By using the coefficient a and a coefficient of variation of the wavelength emitted with the temperature of the device (for example equal to 0.09 nm/° C.) it is possible to calculate the temperature rise in ° C. as a function of the electrical power supplied by the control unit (in W), and to obtain the characteristic of the heating controlled by the control unit ° C./W.

In the case in particular where a temperature sensor is in thermal contact with the active zone or zones it is possible to proceed without prior calibration by measuring directly the variations of the temperature of the device as a function of the power supplied to the heater by the control unit.

In accordance with or more examples the nominal temperature is higher than about 45° C., preferably higher than or equal to 70° C., and it is possible to choose a set point temperature equal to about said nominal temperature.

In the case for example of a nominal temperature equal to 70° C. and a variation of the temperature of the device from 70° C. to 20° C. because of use in a cold environment the heater therefore produces a heating of about 50° C. to revert to the nominal operating temperature of 70° C. and to restore the nominal operating performance of the device 400 according to the present description.

The applicants have observed that if the set point temperature is chosen to be about equal to the nominal operating temperature of the device 400 the heating produced by the heater 460 as described hereinabove makes it possible to improve the performance of the device 400 by limiting the variations of the wavelength and of the power emitted by the device 400 relative to operation at nominal temperature.

In particular, maintaining the emission wavelength of the device in the event of variation of the exterior temperature enables use of telecommunication channels at closer together wavelengths and thereby an increased overall bit rate of a telecommunication network.

Alternatively, the applicants have shown that it is possible to choose a set point temperature strictly less than the nominal temperature.

The compensation of the temperature variation of the device 400 is then only partial but sufficient to improve the performance of the device 400 relative to a prior art device and moreover enables reduction of the electrical power consumption of the heater 460 (and therefore of the device 400), which is advantageous for the applications described hereinabove.

It is therefore possible to choose a set point temperature to select the temperature range of the device over which the heater 460 operates and therefore to choose the desired maximum electrical power consumption.

For example, in the case of a range of variation of the exterior temperature between 20° C. and 70° C. and for a device having a nominal temperature equal to 70° C. it is possible in a first operating mode to choose a set point temperature equal to about the nominal temperature, that is to say about equal to 70° C., and the heater 460 therefore operates over all the exterior temperature range (between 20 C. and 70° C.). For example for an efficiency of the heater 460 of 50° C./W, the latter consumes a maximum of about 1 W because it must in particular produce heating of the active zone to 50° C. when the exterior temperature is 20° C.

In a second operating mode, if the set point temperature chosen is equal to 40° C. (that is to say strictly lower than the nominal temperature), then the temperature range of the device over which the heater 460 operates is reduced to an exterior temperature range between 20° C. and 40° C. The heater then consumes a maximum of about 400 mw because it is at most necessary to produce heating of the active zone only from 20° C. to reach 40° C. when the exterior temperature is 20° C.

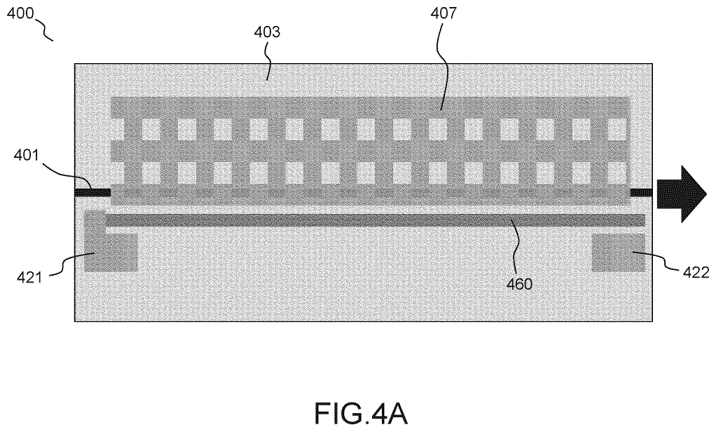

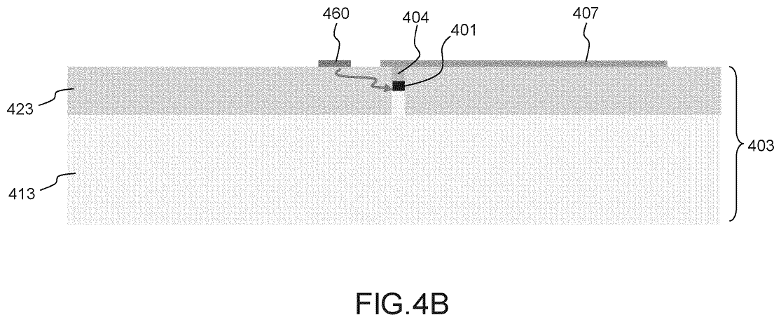

FIG. 4A-4B represent a first example of a light-emitting device 400 according to the present description in a view from above (FIG. 4A) and in section perpendicular to the direction of propagation of light in the device (FIG. 4B).

In the examples depicted in FIG. 4A-4B the device 400 is a device of LC or DML type comprising a laser part but no part able to modulate the light emitted by the laser part (such as an EAM, for example).

Generally speaking, the device 400 comprises a set of layers of semiconductor materials 403, said set of layers forming in particular an active zone 401 configured to emit light.

As represented in FIG. 4B the set of layers of semiconductor materials 403 comprises a lower layer 413, a layer 423 in which the active zone 401 is formed and an upper layer 404 on the opposite side of the layer 423 to the lower layer.

The set of layers of semiconductor materials 403 may for example form a PIN junction type structure with P-doped or N-doped semiconductor materials and an active zone 401 configured to emit light. Light emitted by the active zone 401 is guided along the active zone because of the index contrast with the layer 423, which may comprise materials different from the materials of the upper layer 404, for example such as semi-insulating material (InP doped with iron for example) or materials identical to the layer 404 (P-doped InP).

In the present description there is referred to as the laser or laser part said set of layers of semiconductor materials 403 that in particular forms said active zone 401 enabling emission of light.

The laser is electrically powered in this example via two electrodes, one being the electrical contact electrode 407 for the supply of electrical power to the laser and the other being the electrical ground of the device, for example the lower layer 413 opposite the contact 407 relative to the layer 423.

The device 400 further comprises a heater 460 configured to heat the active zone 401 and to enable a rise in the temperature of the device to the set point temperature using the operating modes described hereinabove for example. The heater 460 is disposed along the active zone 401, for example at a distance at most equal to about 100 micrometers over more than about 70% of the length of the active zone 401.

The applicants have observed that by placing the heater all along the active zone 401 of the device it is possible to maintain a homogeneous temperature over the entire length of the active zone 401, in order in particular to preserve a constant refractive index in the active zone 401. A constant refractive index in particular makes it possible to maintain a stable laser emission wavelength for the device.

The applicants have observed that the optimum distance from the heater 460 and the active zone 401 is the result of a compromise. The aim is the shortest possible distance to optimize the efficacy of the heating of the active layer 401 but sufficient to prevent electrical contact between the heater 460 and the electrode 407. The applicants have observed that a distance between about 5 micrometers and 100 micrometers between the heater and the active zone 401 can achieve said compromise.

The heater 460 may be manufactured using various technologies.

In the example from FIGS. 4A-4B the heater 460 is for example surface metal, for example Ni-Cr, strip disposed on the set of layers of semiconductor materials 403 with two points 421, 422 of electrical contact at respective opposite ends of the heater 460.

The two points 421, 422 of electrical contact are configured to receive an electrical voltage or current command for controlling the heater 460 by means of a control unit (see FIGS. 3A, 3B) that is not represented in FIGS. 4A, 4B. The electrical command in particular enables activation of the production of heat by the Joule effect because of the electrical resistance of the metal strip.

In accordance with other embodiments the heater may also be started up by supplying a voltage via the electrical contact zone 422 the electrical contact 421 being connected to the electrical ground of the component.

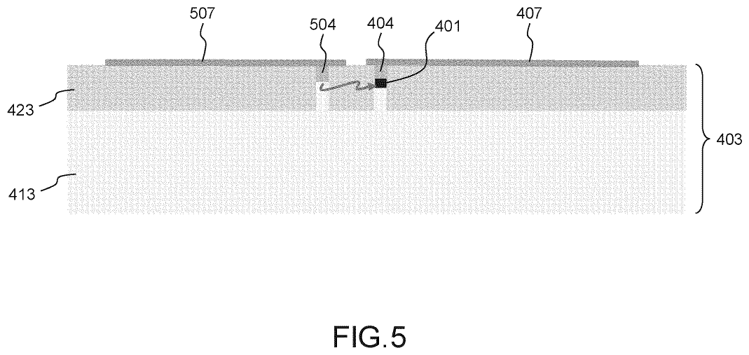

In other embodiments, one example of which is depicted in FIG. 5, the heater forms a diode 504 that is produced in the set 403 of layers of semiconductor materials, for example a PN or PIN-type diode, parallel to the waveguide formed by the active zone 401 and produced in the layers of semiconductor materials the device. The diode consumes electrical energy when an electric voltage is applied to it or a current is injected into it. The diode is preferably such as to emit no or very few photons so that the consumption of electrical energy is reflected in self-heating by the Joule effect, thus enabling heating of the nearby active zone 401.

In this example the diode is supplied with electrical energy via two electrodes, a surface electrode 507 on the same side as the set of layers of semiconductor materials 403 as said contact electrode 407 and a ground electrode arranged on the opposite side, for example the lower layer 413 of the set 403 of layers of semiconductor materials.

The applicants have shown that the diode 504 has the advantage of being able to produce heating in depth in the set of layers of semiconductor materials 403. That is to say that in contrast to a metal strip essentially heating an external surface of the set of layers 403 and then by thermal conduction the active zone 401, the PN diode heats the interior of the set of layers 403 and therefore heats the active zone 401 more effectively.

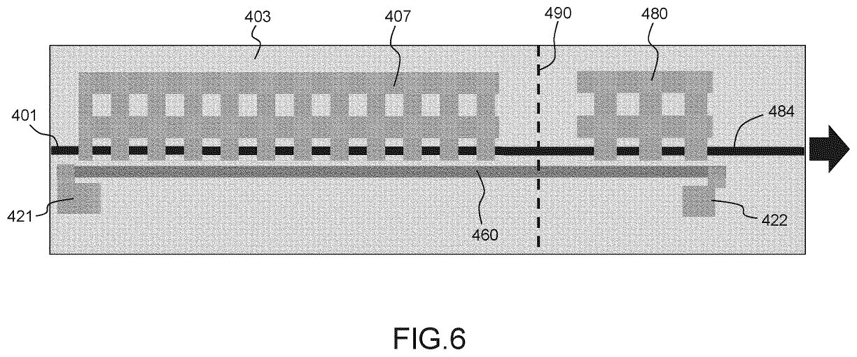

FIG. 6 represents a second example of the light-emitting device. As in the first example depicted in FIGS. 4A, 4B the device comprises a set of layers of semiconductor materials 403. However, in this example the set of layers of semiconductor materials 403 is configured to form in addition to the first active zone 401 a second active zone 484 configured to receive and to modulate light emitted by the first active zone 401. In FIG. 6 a dashed line 490 indicates a delimitation between the first active zone 401 and the second active zone 484.

In this example the second active zone 484 is supplied with electrical energy by two electrodes. One of said electrodes is a modulation contact electrode 480 configured to receive an electrical signal with varying voltage or current controlling the modulation of light emitted by the first active zone 401. The other electrode is the ground of the second active zone 484 (not visible in FIG. 6) and may be electrically connected to the ground of the first active zone 401.

The device according to this second example may be configured to form an EML type device comprising a first active zone 401 emitting light (the laser part) and a second active zone 484 producing modulation of that light (the modulator part).

In the present description modulation of light emitted by the set 403 is to be understood as modification of a parameter of the light, for example the phase or the amplitude.

In the FIG. 6 example the heater 460 extends along the first active zone 401 and the second active zone 484 in order to be able to produce simultaneous and homogeneous heating of the two active zones 401, 484 as described hereinabove.

### The Applicants Have Demonstrated That Simultaneous

heating of the two active zones 401, 484 makes it possible, on the one hand, to limit the variations of the emission wavelength and of the power of the light emitted by the device 400 and, on the other hand, to maintain a satisfactory extinction curve. This therefore enables the device to preserve optimum performance in the event of an exterior temperature variation, in particular in terms optical power and of depth of modulation of that optical power.

In FIG. 4A and FIG. 6, to show the positions of the waveguide 401 and the first and second active zones relative to the heater 460, the waveguide 401 and the active zones are visible as if by transparency although they are not on the upper layer of the first set of layers of semiconductor materials 403, as can be seen in FIG. 4B. In a general case the waveguide 401 is not always visible in a view from above of the device 400. In some embodiments of the device 400 comprising a buried type waveguide 401 the presence and the disposition of the waveguide 401 can nevertheless be identified indirectly in a view from above of the device 400 by a variation of relief on the visible surface of the device.

According to the first and second examples the set of layers of semiconductor materials 403 is advantageously optimized to operate at a high nominal temperature, for example around 70° C. Optimization may, for example, comprise a choice of particular structures for the active zones 401, 484. In particular, said active zones may be configured to produce strong confinement of the electrons in the conduction band to limit the impact of the temperature of the device on the performance of the device.

Optimization may also be effected by choosing structures comprising materials with a forbidden energy band enabling an optimum laser emission gain or extinction curve at high temperature.

Generally speaking, the set of layers of semiconductor materials 403 may be configured to form different types of active zone, such as a distributed Bragg grating, for example.

Moreover, as an alternative to the FIG. 6 example, a second active zone may be formed by a second set of layers of semiconductor materials (not represented in the figures) disposed so as to be able to receive light emitted by the first set of layers of semiconductor materials. For example, the arrangement of the first and second sets of layers of semiconductor materials may employ a butt-joint technique, that is to say the first and second sets of layers of semiconductor materials are arranged end-to-end with their active zones aligned the one relative to the other and in contact in accordance with a technique known to the person skilled in the art. In this example the heater further extends along the second active zone formed by said second set of layers of semiconductor materials.

Although described by means of a number of embodiments, the light-emitting systems according to the present invention encompass different variants, modifications and improvements that will be evident to the person skilled in the art, it being understood that these different variants, modifications and improvements fall within the scope of the invention as defined by the following claims.

### REFERENCES

[Ref 1] SASADA, Noriko, NAKAJIMA, Takayuki, SEKINO, Yuji, et al. Wide-Temperature-Range (25-80° C.) 53-Gbaud PAM 4 (106-Gb/s) Operation of 1.3-μm Directly Modulated DFB Lasers for 10-km Transmission. Journal of Lightwave Technology, 2019, vol. 37, no. 7, p. 1686-1689.
[Ref 2] NAKAI, Yoshihiro, NAKANISHI, Akira, YAMAGUCHI, Yoriyoshi, et al. Uncooled Operation of 53-GBd PAM 4(106-Gb/s) EA/DFB Lasers with Extremely Low Drive Voltage With 0.9 V pp. Journal of Lightwave Technology, 2019, vol. 37, no. 7, p. 1658-1662.

1. An uncooled light-emitting system (100) comprising:
a light-emitting device (400) comprising:
at least one first set of layers of semiconductor materials (403) configured to form at least one first active zone (401) able to emit light, said first active zone (401) being optimized to function at a nominal temperature; and
a heater (460) extending at least along said first active zone (401) and situated at a predetermined maximum distance from said first active zone (401) less than or equal to about 100 micrometers, said heater being configured, in operation, to produce a heating of said first active zone (401);
means (500) for determining the temperature of the device; and
a control unit (600) configured to start up said heater (460) only if said temperature of the device is strictly lower than predetermined set point temperature less than or equal to said nominal temperature, the heating produced by the heater enabling a rise in the temperature of the device to about the value of the set point temperature.

2. The system as claimed in claim 1, in which the means (500) for determining the temperature of the device comprise a temperature sensor.

3. The system as claimed in claim 2, in which the temperature sensor is thermally insulated from said at least one first active zone of the device so as to measure a temperature exterior to the device (400).

4. The system as claimed in claim 2, in which the temperature sensor is in thermal contact with said at least one first active zone of the device (400).

5. The system as claimed in any one of the preceding claims, in which said maximum distance between the active zone (401) and the heater (460) is a distance between about 5 micrometers and about 100 micrometers.

6. The system as claimed in any one of the preceding claims, in which said maximum distance between the active zone (401) and the heater (460) is a distance between about 5 micrometers and about 20 micrometers.

7. The system as claimed in any one of the preceding claims, in which the means (500) for determining the temperature of the device comprise a device for measuring the wavelength of the light emitted by the light-emitting device.

8. The system as claimed in any one of the preceding claims, in which said set point temperature is strictly lower than said nominal temperature.

9. The system as claimed in any one of the preceding claims, in which the heater (460) comprises a metal strip disposed on an external layer of said first set of layers of semiconductor materials (403).

10. The system as claimed in any one of claims 1 to 8, in which the heater (460) is produced in layers of the set of layers of semiconductor materials (403) in the form of a PN or PIN diode.

11. The system as claimed in any one of the preceding claims, in which said heater (460) comprises at least one ground (421) electrically connected to a ground of said set of layers of semiconductor materials (403) and at least one electrical contact (422) electrically insulated from said ground (421).

12. The system as claimed in any one of the preceding claims, in which said first active zone (401) forms a distributed Bragg grating laser.

13. The system as claimed in any one of the preceding claims, in which:
said first set of layers of semiconductor materials (403) is further configured to form a second active zone (484) able to receive and to modulate light emitted by said first active zone (401), said second active zone being optimized to function at said nominal temperature; and
said heater (460) further extends along said second active zone (484) and is disposed at said maximum distance from said second active zone (484), said heater further being configured to produce a heating of said second active zone (484).

14. The system as claimed in any one of claims 1 to 12, in which:
the device comprises a second set of layers of semiconductor materials configured to form a second active zone able to receive and to modulate light emitted by said first active zone, said second active zone being optimized to function at said nominal temperature; and
said heater further extends along said second active zone and is disposed at said maximum distance from said second active zone, said heater being further configured to produce heating of said second active zone.

15. The system as claimed in either one of claims 13 or 14, in which said second active zone forms an electro-absorption modulator.

16. A method of controlling the temperature in an uncooled light-emitting system as claimed in any one of the preceding claims, said method comprising:
choosing a set point temperature lower than or equal to said nominal temperature of the device;
determining the temperature of the device; and
the control unit (600) starting up the heater only if said temperature of the device is strictly lower than said set point temperature, the heating produced by the heater enabling a rise in the temperature of the device to about the value of said set point temperature.

17. The method as claimed in claim 16, further comprising:
prior calibration of the control unit (600), said calibration comprising establishing a power-heating characteristic that characterizes the rise in temperature of the device as a function of an electrical power supplied to the heater (460) by the control unit (600) to produce heat.
